(19) United States
(12) Patent Application Publication
(10) Pub. No.: US 2016/0365137 A1
(43) Pub. Date: Dec. 15, 2016

(54) Pre-Emphasis and Equalization for DRAM

(71) Applicant: Broadcom Corporation, Irvine, CA (US)

(72) Inventor: Reinhard C. SCHUMANN, Exeter, NH (US)

(73) Assignee: Broadcom Corporation, Irvine, CA (US)

(21) Appl. No.: 15/177,925

(22) Filed: Jun. 9, 2016

Related U.S. Application Data
(60) Provisional application No. 62/174,133, filed on Jun. 11, 2015.

(51) Int. Cl. G11C 11/4093; G11C 11/4094; G11C 11/4096

(52) U.S. Cl. CPC G11C 11/4093; G11C 11/4096; G11C 11/4094

(57) ABSTRACT

The present disclosure is directed to apparatuses and methods to pre-compensate and/or post-compensate for inter-symbol interference (ISI). The apparatuses and methods of the present disclosure can be implemented as part of an I/O interface in a memory or memory controller, including dynamic random access memory (DRAM).

### CROSS REFERENCE TO RELATED APPLICATIONS

This application claims the benefit of U.S. Provisional Patent Application No 62/174,133, filed Jun. 11, 2015, which is incorporated by reference herein in its entirety.

### TECHNICAL FIELD

This application relates generally to pre-emphasis and equalization, including pre-emphasis and equalization for dynamic random-access memory (DRAM).

### BACKGROUND

The rate at which data is communicated over DRAM data buses continues to increase. For example, the 4^{th} generation JEDEC low-power double data rate (LPDDR4) RAM interface RAM interface uses higher data transfer rates than JEDEC's previous third generation LPDDR (LPDDR3) RAM interface.

As data transfer rates have increased, bandwidth limitations of the data bus transmission channel (e.g., circuit board traces) between the DRAM and the chip controlling the DRAM have become more of an issue. In particular, because of high-frequency signal loss of the transmission channel, the high-frequency content of a level change (e.g., high-low or low-high) from a first bit to a second bit in the data signal may take longer than the bit interval of the second bit. If the level change takes longer than the bit interval of the second bit (meaning that the second bit cannot completely reach a logic high or logic low level before the arrival of the next bit), than the second bit may not be recovered properly.

For example, if the first bit is transmitted at a low level logic “0” and the second bit is transmitted at a high level logic “1”, and the level change from the low level of the first bit to the high level of the second bit takes longer than the bit interval of the second bit due to high-frequency signal loss of the transmission channel, the receiver may incorrectly interpret the second bit as a logic “0”, In general, the low level of the first bit interferes with the high level of the second bit. Thus, this interference between bits is often referred to as intersymbol interference (ISI).

### BRIEF DESCRIPTION OF THE DRAWINGS/FIGURES

The accompanying drawings, which are incorporated herein and form a part of the specification, illustrate the present disclosure and, together with the description, further serve to explain the principles of the disclosure and to enable a person skilled in the pertinent art to make and use the disclosure.

FIG. 1 illustrates an exemplary operating environment in which embodiments of the present disclosure can be implemented.

FIG. 2 illustrates an ISI post-compensation circuit in accordance with embodiments of the present disclosure.

FIG. 3 illustrates another ISI post-compensation circuit in accordance with embodiments of the present disclosure.

FIG. 4 illustrates an ISI pre-compensation circuit in accordance with embodiments of the present disclosure.

FIG. 5 illustrates a waveform diagram of the operation of an ISI pre-compensation circuit in accordance with embodiments of the present disclosure.

FIG. 6 illustrates an ISI pre-compensation circuit in accordance with embodiments of the present disclosure.

The present disclosure will be described with reference to the accompanying drawings, The drawing in which an element first appears is typically indicated by the leftmost digit(s) in the corresponding reference number.

### DETAILED DESCRIPTION

In the following description, numerous specific details are set forth in order to provide a thorough understanding of the disclosure. However, it will be apparent to those skilled in the art that the disclosure, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring aspects of the disclosure.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of this discussion, the term “device” shall be understood to include software, firmware, or hardware (such as one or more circuits, microchips, and/or processors), or any combination thereof. In addition, it will be understood that each device can include one, or more than one, component, and each component that forms a part of the described device can function either cooperatively or independently of any other component forming a part of the device. Conversely, multiple devices described herein can represent a single component.

### 1. Exemplary Operating Environment

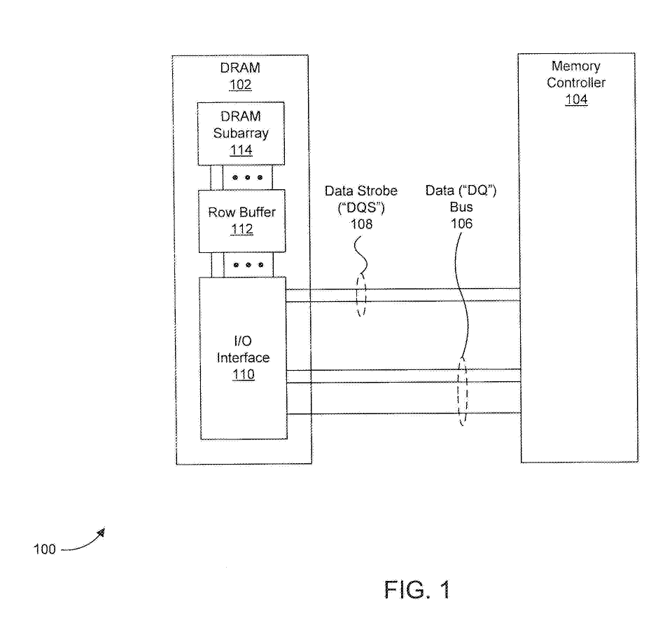

FIG. 1 illustrates an exemplary operating environment 100 in which embodiments of the present disclosure can be implemented. Operating environment 100 includes a dynamic random-access memory (DRAM) 102 and a memory controller 104. DRAM 102 and memory controller 104 are coupled together via a data (“DQ”) bus 106 and a data bus strobe (“DQS”) 108. Other connections, such as an address bus. are omitted for the sake of clarity.

Data bus 106 includes a plurality of single-ended data lines (e.g., circuit board traces) that each communicate data in one direction or hi-directionally between DRAM 102 and memory controller 104. Data bus strobe 108 is a bidirectional or single direction differential control line used to synchronize the transfer of data between DRAM 102 and memory controller 104 over data bus 106. The device transmitting over data bus 106 (e.g., either DRAM 102 or memory controller 104) at any given time sends a synchronization signal over data bus strobe 108.

As further shown in FIG. 1, DRAM 102 includes an input/output (I/O) interface 110, a row buffer 112, and a DRAM subarray 114. In this embodiment of FIG. 1, I/O interface 110 is configured in accordance with JEDEC's fourth generation low-power double data rate (LPDDR4) memory interface specification. I/O interface 110 can include, among other components, a line driver to drive data signals over data bus 106, a line receiver to receive data signals over data bus 106, and registers to store the data received and/or to be transmitted over data bus 106. Row buffer 112 is used to read and write data to DRAM subarray 114 and can include, for example, a row of sense amplifiers. DRAM subarray 114 includes an array of DRAM cells organized, for example, in rows and columns.

Because of the high data transfer rates used by the LPDDR4 memory interface specifications in which I/O interface 110 is implemented in accordance with, bandwidth limitations of data bus 106 can result in ISI. The present disclosure provides apparatuses and methods to pre-compensate and/or post--compensate for such ISI. The apparatuses and methods of the present disclosure can specifically be implemented as part of I/O interface 110.

It should be noted that an I/O interface similar to I/O interface 110 can be implemented in memory controller 104. Such an I/O interface in memory controller 104 can further include the apparatuses and methods of the present disclosure to pre-compensate and/or post-compensate for ISI as will be appreciated by one of ordinary skill in the art.

### 2. ISI Post-Compensation

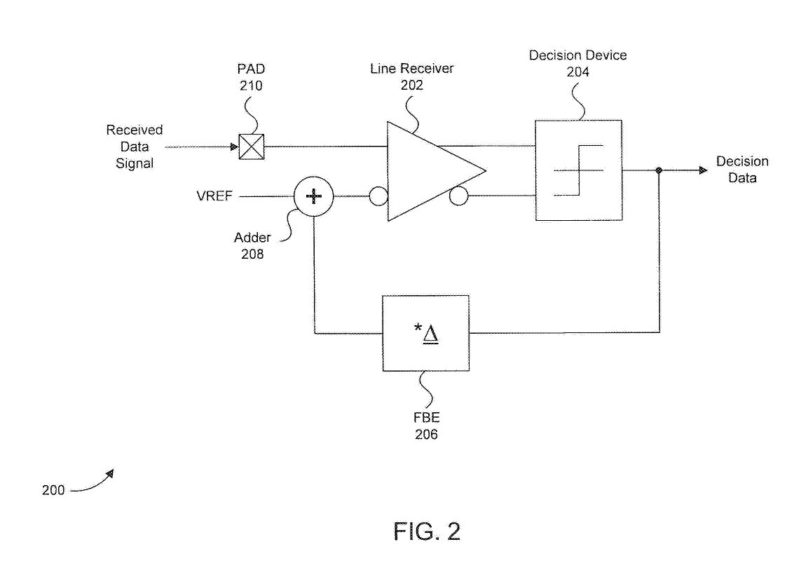

Referring now to FIG. 2, an ISI post-compensation circuit 200 is illustrated in accordance with embodiments of the present disclosure. ISI, post-compensation circuit 200 can be implemented within DRAM 102 or memory controller 104 for each single-ended data line of data bus 106 to compensate for ISI in the data signal received over the single-ended data line.

As shown in FIG. 2, ISI post-compensation circuit 200 includes a line receiver 202, a decision device 204 (e.g., a flip-flop or slicer), a feedback equalizer (FBE) 206, and an adder 208. For the simple case of non-return-to-zero (NRZ) data used in the LPDDR4 signaling, the decision data for a bit of the received data signal at the output of ISI post-compensation circuit 200 is either a logic “0” or a logic “1”.

The decision data for a current bit at the output of ISI post-compensation circuit 200 is fed back to FBE 206, which generates an ISI compensation factor equal to either +Δ or −Δ based on whether the decision data for the current bit is either a logic “0” or logic “1”. If the decision data is a logic “0”, FBE 206 outputs −Δ, and if the decision data is a logic “1”, FBE 206 outputs +Δ. The ISI compensation factor is then added by adder 208 to the reference voltage (VREF) used as a threshold value to decide whether the next bit of the received data signal is either a logic “0” or a logic “1”

The adjusted VREF at the output of adder 208 and the next bit of the received data signal (i.e., the bit immediately following the current bit decided at the output of ISI post-compensation circuit 200) are subsequently input to respective differential inputs of line receiver 202. Line receiver 202 is an amplifier configured to amplify the signal across its differential inputs. The output of line receiver 202 is then input into decision device 203, which determines the next bit of the received data signal to be a logic “1” if the next bit has a voltage above the adjusted VREF at the output of adder 208, or a logic “0” otherwise.

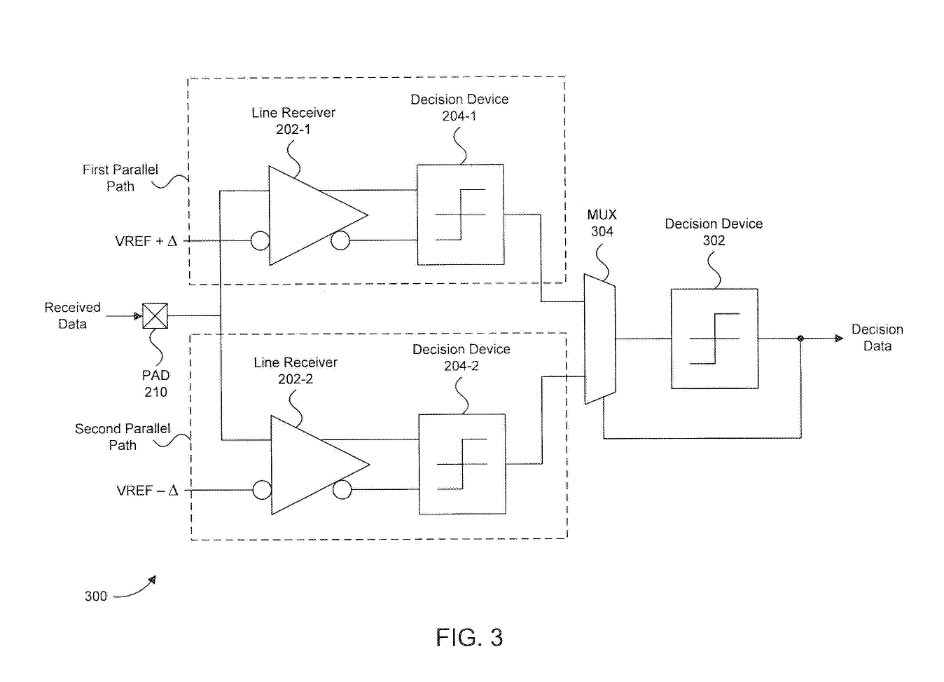

FIG. 3 illustrates another ISI post-compensation circuit 300 in accordance with embodiments of the present disclosure. ISI post-compensation circuit 300 has a similar configuration as ISI post-compensation circuit 200 in FIG. 2 and can be implemented within DRAM 102 or memory controller 104 for each single-ended data line of data bus 106. However, the loop (or path) in which the computation of FBE 206 in FIG. 2 is performed has been “un-rolled.”

As illustrated in HG. 3, rather than waiting for decision device 302 to determine whether a currently processed bit of the received data signal is either a logic “0” or a logic “1”. ISI post-compensation circuit 300 has two parallel paths that each use a constant VREF. with one of the parallel paths adjusting the constant VREF by +Δ and the other one of the parallel paths adjusting VREF by −Δ, thereby reflecting the two possible outputs of the adder 208 in FIG. 2.

Specifically, the first parallel path of ISI post-compensation circuit 300, which includes line receiver 202-1 and decision device 204-1, presupposes that decision device 302 determines the currently processed bit of the received data signal to be a logic “1”. Based on this presupposition, VREF +Δ is input into one input of line receiver 202-1 and the next bit of the received data signal is input into the other input of line receiver 202-2. The output of line receiver 202-1 is then input into decision device 204-1 (e.g., a flip-flop), which determines the next bit of the received data signal to be a logic “1” if the next bit has a voltage above the adjusted VREF +Δ. or a logic “0” otherwise.

The second parallel path of ISI post-conpensation circuit 300, which includes line receiver 202-2 and decision device 204-2, presupposes that decision device 302 determines the currently processed bit of the received data signal to be a logic “0”. Based on this presupposition, VREF +Δ is input into one end of line receiver 202-2 and the next bit of the received data signal is input into the other end of line receiver 202-2. The output of line receiver 202-2 2 is then input into decision device 204-2 (e.g., a flip-flop), which determines the next bit of the received data signal to be a logic “1” if the next bit has a voltage above the adjusted −Δ. or a logic “0” otherwise.

Once decision device 302 actually determines the value of the current bit of the received signal, the determined value can be used as the select input to multiplexer 304 to select the output of the corresponding parallel path for the current bit of the received signal.

### 3. ISI Pre-Compensation

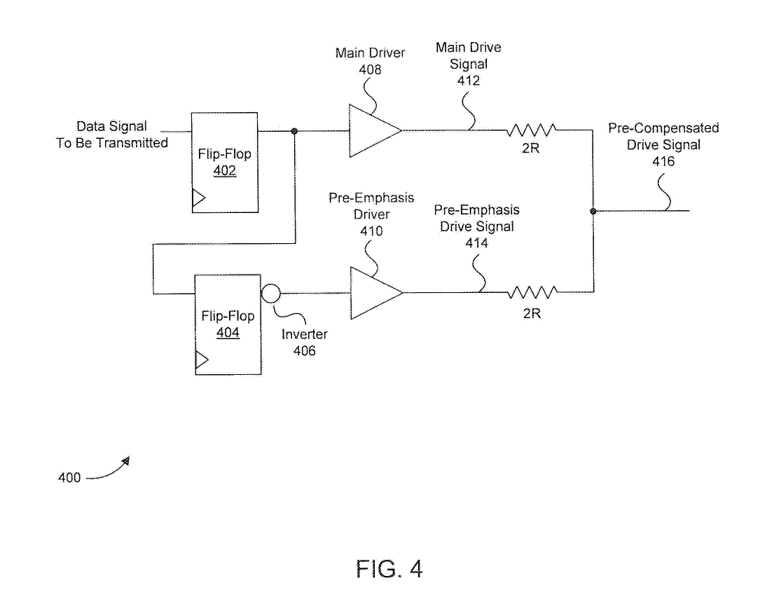

Referring now to FIG. 4, an ISI pre-compensation circuit 400 is illustrated in accordance with embodiments of the present disclosure. ISI pre-compensation circuit 400 can be implemented within DRAM 102 or memory controller 104 for each single-ended data line of data bus 106 to pre-compensate for ISI on the data signal to be transmitted over the single-ended data line. As shown in FIG. 4, ISI pre-compensation circuit 400 includes two flip-flops 402 and 404, an inverter 406, and two drivers: a main driver 408 and a pre-emphasis driver 410. Main driver 408 and pre-emphasis driver 410 are amplifiers configured to drive a load (e.g., a data line) connected to their outputs. The drive voltage of main driver 408 is greater than the drive voltage of pre-emphasis driver 410. In one embodiment, flip-flops 402 and 404 are clocked by the same clock at the data rate at which the data signal to be transmitted is received by flip-flop 402.

In general, ISI pre-compensation circuit 400 is configured to “pre-emphasize” bits in the data signal to be transmitted that follow a transition from one logic state to another so as to pre-compensate for the high-frequency signal loss of the transmission channel of data bus 106 shown in FIG. 1. More specifically, for a bit transition from a logic “0” to a logic “1”, the logic “1” is “pre-emphasized” by driving the logic “1” to a higher voltage than what would be done under normal conditions (i.e., above the voltage level Voh corresponding to the logic “1” value under normal conditions). In the opposite case, for a bit transition from a logic “1” to a logic “0”, the logic “0” is “pre-emphasized” by driving the logic “0” to a lower voltage than what would be done under normal conditions (i.e., below the voltage level corresponding to the logic “0” value under normal conditions). ISI pre-compensation circuit 400 can output the normal voltage levels that correspond to logic “0” and logic “1” for a bit that does not result from a bit transition (i.e., for a bit that does not immediately come after a bit with the opposite logic value).

In typical LPDDR4 interfaces, a logic “0” corresponds to 0V. In a single-supply circuit, the line driver is unable to drive any lower than 0V. In order to pre-emphasize a logic “0”, it would normally be necessary to drive the signal to a negative voltage, requiring a negative supply voltage. To avoid this requirement, the pre-emphasis drive signal, which would normally be, for example, a +/−25 mV voltage symmetric around zero, can be biased upward by, for example, 25 mV so that it is 0 to 50 mV. This has the side effect of biasing the entire pre-compensated drive signal up by 25 mV and the receiver threshold must be adjusted accordingly.

As can be seen from FIG. 4, assuming flip-flops 402 and 404 are clocked by the same clock (not shown) at the data rate of the data signal to be transmitted, flip-flop 402 would store a “current bit” of the data signal to be transmitted (i.e., the most recently received bit of the data signal to be transmitted) and flip-flop 404 would store the bit of the data signal that was received just before the current bit (i.e., the “previous bit”) stored in flip-flop 402. Thus, when the current bit stored in flip-flop 402 is a logic “0” and the previous bit stored in flip-flop 404 is also a logic “0”, main driver 408 will sink current from the load at its output and, because of inverter 406 at the output of flip-flip 404, pre-emphasis driver 410 will source current to the load at its output. When the current bit stored in flip-flop 402 is a logic “1” and the previous bit stored in flip-flop 404 is a logic “0”, main driver 408 will source current to the load at its output and pre-emphasis driver 410 will also source current to the load at its output. When the current bit stored in flip-flop 402 is a logic “1” and the previous bit stored in flip-flop 404 is also a logic “1”, main driver 408 will source current to the load at its output and pre-emphasis driver 410 will sink current from the load at its output. Finally, when the current bit stored in flip-flop 402 is a logic “0” and the previous bit stored in flip-flop 404 is also a logic “0”, main driver 408 will sink current from the load at its output and pre-emphasis driver 410 will source current to the load at its output.

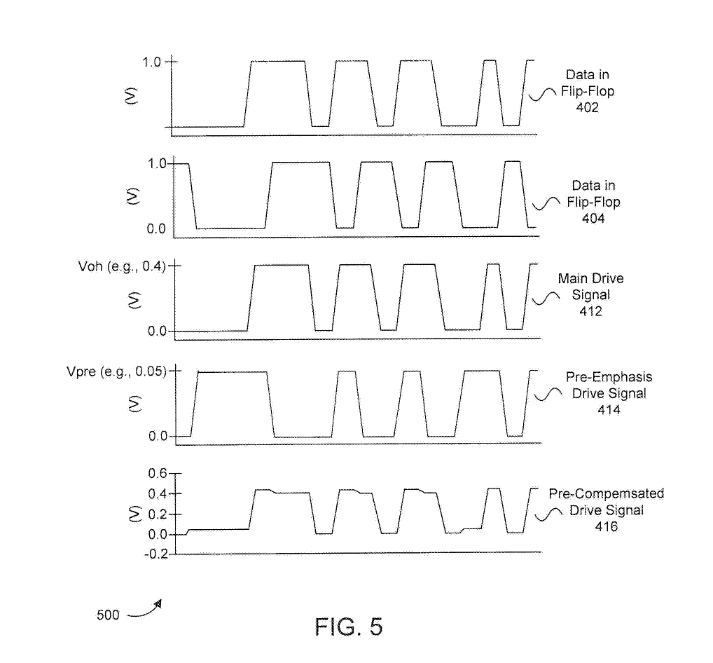

FIG. 5 illustrates a waveform diagram 500 of example waveforms corresponding to values stored in flip-flops 402 and 404 in FIG. 4, the main drive signal 412 output by main driver 408 in FIG. 4, the pre-emphasis drive signal 414 output by pre-emphasis driver 410, and the pre-compensated drive signal 416 or final output of ISI pre-compensation circuit 400 in FIG. 4. As can be seen from the waveforms shown, in FIG. 5, the combination of main drive signal 412 provided by main driver 408 and the pre-emphasis drive signal 414 provided by pre-emphasis driver 410 results in a pre-compensated drive signal 416 that has been “pre-emphasized” as described above to pre-compensate for ISI on the data signal to be transmitted. It should be noted that the voltage levels Vpre and Voh shown in FIG. 5 are for exemplary purposes only. Other voltage levels can be used as would be appreciated by one of ordinary skill in the art.

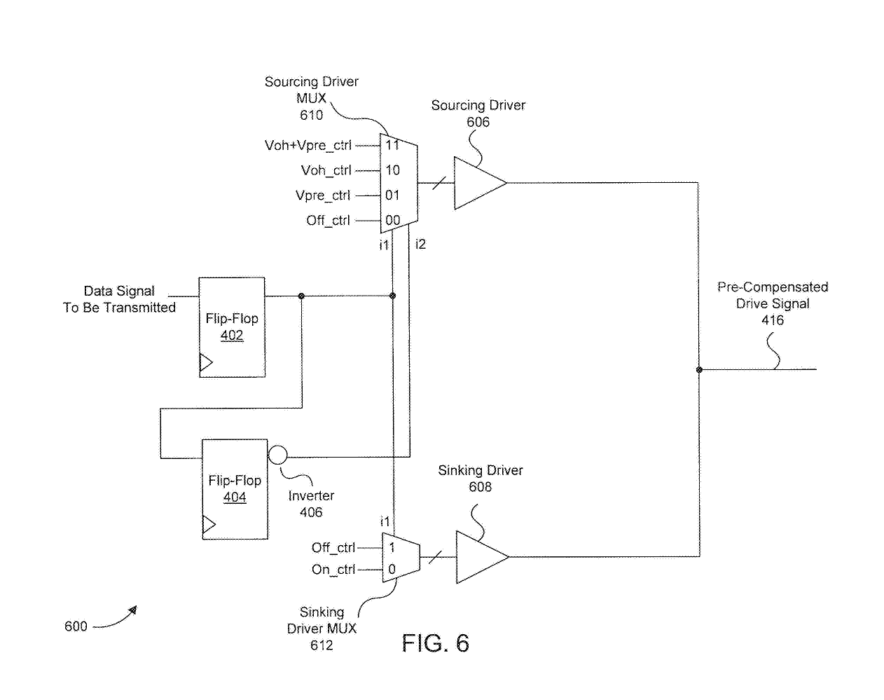

Referring now to FIG. 6, another implementation of an ISI pre-compensation circuit 600 is illustrated in accordance with embodiments of the present disclosure. ISI pre-compensation circuit 600 can be implemented within DRAM 102 or memory controller 104 for each single-ended data line of data bus 106 to pre-compensate for ISI on the data signal to be transmitted over the single-ended data line. In general, ISI pre-compensation circuit 600 effectively implements the summing of the pre-emphasis and main drive waveforms, which was performed by the ISI pre-compensation circuit 400 in FIG. 4 to generate the pre-compensated drive signal, by using pre-computed sums at the inputs to a sourcing driver 606 and a sinking driver 605. The sourcing driver 608 sources current through zero or more weighted source resistors (internal to sourcing driver 606), The sinking driver 612 sinks current through zero or more weighted sink resistors (internal to sinking driver 608). ISI pre-compensation circuit 600 further includes two multiplexers (MUXs): sourcing driver MUX 610 and sinking driver MUX 612, MUXs 610 and 612 can be analog or digital and, in the case where MUXs 610 and 612 are analog, at least the inputs to sourcing and sinking drivers 606 and 608 can be analog.

As shown in FIG. 6, sourcing driver 606 and sinking driver 608 are configured to respond to control signal values that are output by the respective MUX coupled to their inputs. Sourcing driver MUX 610 is configured to couple one of its four inputs. Voh+Vpre_ctrl, Voh_ctrl, and Off_ctrl, each of which corresponds to a different drive strength value indicated by its name, to the input of main driver 408. Sourcing driver MUX 610 specifically couples one of its four inputs to the input of main driver 408 based on a two-bit MUX control signal (i1 and i2) that corresponds to the outputs of flip-flops 402 and 404. Sourcing driver 606 provides an output signal with a drive strength determined based on the output of sourcing driver mux 610. For example, for the control signal Voh+Vpre_ctrl at the input of sourcing driver 606, sourcing driver 606 provides an output signal with a drive strength voltage of Voh+Vpre.

Similarly, sinking driver MUX 612 is configured to couple one of its two inputs. Off_ctrl and On_l, each of which corresponds to a different drive strength value indicated by its name, to the input of sinking driver 410. Sinking driver MUX 612 specifically couples one of its two inputs to the input of sinking driver 608 based on the output of the one-bit MUX control signal (i1) corresponding to the output of flip-flop 402. Sinking driver 608 provides an output signal with a drive strength determined based on the output of sinking driver mux 612.

In general, the control signal values at the inputs to MUXs 610 and 612 are set such that ISI pre-compensation circuit 600 “pre-emphasizes” bits in the data signal to be transmitted that follow a transition to pre-compensate for the high-frequency signal loss of the transmission channel of data bus 106 shown in FIG. 1. More specifically, for a bit transition from a logic “0” to a logic “1”, the logic “1” is “pre-emphasized” by driving the logic “1” to a higher voltage than what would be done under normal conditions (i.e., above the voltage level corresponding to the logic “1” value). In the opposite case, for a bit transition from a logic “1” to a logic “0”, the logic “0” is “pre-emphasized” by driving the logic “0” to a lower voltage than what would be done under normal conditions (i.e., below the voltage level corresponding to the logic “0” value). ISI pre-compensation circuit 600 can output the voltage levels that correspond to logic “0” and logic “1” for a bit that does not result from a bit transition (i.e., for a bit that does not immediately come after a bit with the opposite logic value).

Note that, for the normal logic “0” case, i.e. for a logic “0” after a preceding logic “0”, the signal is driven slightly above 0V by turning on the sinking driver 612 at full strength and turning on the sourcing driver 608 at weak strength.

### 4. Conclusion

Embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

What is claimed is:

1. An apparatus, comprising:
a data bus; and
an input/output (IO) interface, implemented within a dynamic random-access memory (DRAM) or memory controller, configured to receive the data over a data bus,
wherein the I/O interface comprises an intersymbol interference (ISI) post-compensation circuit configured to add an ISI compensation factor, determined based on a first bit of the data received over the data bus, to a reference voltage used to determine a logic value of a second bit received over the data bus immediately following the first bit of data.

2. The apparatus of claim 1, further comprising:
a dynamic random-access memory (DRAM) subarray for storing data; and
a row buffer configured to write the data to the DRAM subarray,
wherein the I/O interface is configured to receive the data over the data bus from a memory controller.

3. The apparatus of claim 1, wherein the I/O interface is implemented in the memory controller and is configured to receive the data over the data bus from the DRAM.

4. The apparatus of claim 1, wherein the I/O interface is implemented in accordance with a low-power double date rate (LPDDR) RAM interface specification.

5. The apparatus of claim 1, wherein each line of the data bus is coupled to a different instance of the ISI post-compensation circuit.

6. The apparatus of claim 1, wherein the ISI post-compensation circuit includes two parallel paths, each configured to add a different value of the ISI compensation factor to the reference voltage.

7. A dynamic random-access memory (DRAM), comprising:
a DRAM subarray for storing data;
a row buffer configured to read the data from the DRAM subarray; and
an input/output (I/O) interface, configured to transmit the data over a data bus to a memory controller, comprising an intersymbol interference (ISI) pre-compensation circuit configured to pre-emphasize the data before the data is transmitted over the data bus to the memory controller, wherein the ISI pre-compensation circuit comprises:
a first flip-flop comprising a first flip-flop input and a first flip-flop output, wherein the first flip-flop input is configured to receive the data from the DRAM subarray;
a second flip-flop comprising a second flip-flop input and a second flip-flop output, wherein the second flip-flop input is coupled to the first flip-flop output;
a sourcing driver multiplexer (MUX) configured to provide a sourcing driver control signal based on the first flip-flop output and the second flip-flop output;
a sinking driver MUX configured to provide a sinking driver control signal based on the second flip-flop output;
a sourcing driver configured to provide a sourcing drive signal with a drive strength determined based on the sourcing driver control signal; and
a sinking driver configured to provide a sinking drive signal with a drive strength determined based on the sinking driver control signal.

8. The DRAM of claim 7, Wherein the ISI pre-compensation circuit is configured to combine the sourcing drive signal and the sinking drive signal.

9. The DRAM of claim 7, wherein the I/O interface is implemented in accordance with a low-power double date rate (LPDDR) RAM interface specification.

10. The DRAM of claim 7, wherein each line of the data bus is coupled to a different instance of the ISI pre-compensation circuit.

11. The DRAM of claim 7, wherein the ISI pre-compensation circuit is configured to pre-emphasize a logic “1” that follows a logic “0” in the data before the data is transmitted over the data bus to the memory controller by driving the logic “1” on the data bus to a higher voltage than a voltage level corresponding to logic “1” values.

12. The DRAM of claim 7, wherein the ISI pre-compensation circuit is configured to pre-emphasize a logic “0” that follows a logic “1” in the data before the data is transmitted over the data bus to the memory controller by driving the logic “0” on the data bus to a lower voltage than a voltage level corresponding to logic “0” values.

13. The DRAM of claim 7, wherein the sourcing driver MUX is configured to couple one of four different input control signal Values to the sourcing driver based on the first flip-flop output and the second flip-flop output.

14. An intersymbol interference (ISI) pre-compensation circuit for pre-emphasizing data before the data is transmitted over a data bus, comprising:
a first flip-flop comprising a first flip-flop input and a first flip-flop output, wherein the first flip-flop input is configured to receive the data;
a second flip-flop comprising a second flip-flop input and a second flip-flop output, wherein the second flip-flop input is coupled to the first flip-flop output;
a sourcing driver multiplexer (MUX) configured to provide a sourcing driver control signal based on the first flip-flop output and the second flip-flop output;
a sinking driver MUX configured to provide a sinking driver control signal based on the second flip-flop output;
a sourcing driver configured to provide a sourcing drive signal with a drive strength determined based on the sourcing driver control signal; and
a sinking driver configured to provide a sinking drive signal with a drive strength determined based on the sinking driver control signal.

15. The ISI pre-compensation circuit of claim 14, wherein the sourcing drive signal and the sinking drive signal are combined to generate pre-emphasized data.

16. The ISI pre-compensation circuit of claim 15, wherein:
a logic “1” that follows a logic “0” in the data is driven to a higher voltage than a voltage level corresponding to logic “1” values in the pre-emphasized data; and
a logic “0” that follows a logic “1” in the data is driven to a lower voltage than a voltage level corresponding to logic “0” values in the pre-emphasized data.

17. The ISI pre-compensation circuit of claim 14, wherein the ISI pre-compensation circuit is implemented in an input/output (I/O) interface.

18. The ISI pre-compensation circuit of claim 14, wherein the I/O interface is implemented in accordance with a low-power double date rate (LPDDR) RAM interface specification.

19. The ISI pre-compensation circuit of claim 14, wherein ISI pre-compensation circuit is implemented in a memory controller.

20. The ISI pre-compensation circuit of claim 14, wherein ISI pre-compensation circuit is implemented in a dynamic random access memory (DRAM).
